(19) United States
(12) Patent Application Publication
(10) Pub. No.: US 2022/0109287 A1
(43) Pub. Date: Apr. 7, 2022

(54) Metalens Array and Vertical Cavity Surface Emitting Laser Systems and Methods

(71) Applicants: Alan Lenef, Belmont, MA (US); Fabian Knorr, Postbauer-Heng (DE); Klein Johnson, Orono, MN (US); Dadi Setiadi, Edina, MN (US); Maryam Khodami, Exeter, NH (US)

(72) Inventors: Alan Lenef, Belmont, MA (US); Fabian Knorr, Postbauer-Heng (DE); Klein Johnson, Orono, MN (US); Dadi Setiadi, Edina, MN (US); Maryam Khodami, Exeter, NH (US)

(73) Assignees: Vixar, Inc., Plymouth, MN (US); OSRAM Opto Semiconductors GmbH, Regensburg (DE)

(21) Appl. No.: 17/060,607

(22) Filed: Oct. 1, 2020

(51) Int. Cl. H01S 5/42; H01S 5/183; H01S 5/02

(52) U.S. Cl. CPC H01S 5/423; H01S 5/021; H01S 5/18388

(57) ABSTRACT

The present disclosure is directed to systems and methods useful for providing a low profile metalens array that provides a relatively uniform far-field illumination in the visible and/or near-infrared electromagnetic spectrum using a plurality of vertical cavity surface emitting lasers (VCSELs) disposed a distance from a plurality of metalenses forming a metalens array, in which the VCSELs are decorrelated from the metalenses forming the metalens array.

### TECHNICAL FIELD

The present disclosure relates to illumination systems and methods, more specifically to systems and methods for generating a desired far-field illumination pattern.

### BACKGROUND

Vertical cavity surface emitting laser (VCSEL) arrays are important visible and infra-red (IR) light sources in many applications, including dot display patterns for face recognition, uniform illumination for biometrics (face recognition), gesture recognition, LiDAR, sensing, and other applications. Such arrays can operate both in continuous and pulsed modes at eye-safe power levels. The individual VCSELs are characterized by relatively narrow divergence, azimuthal symmetry in the beam pattern, and high power with low speckle when used in arrays. These are all good characteristics for laser-based illumination.

### BACKGROUND

Various implementations disclosed herein include an illumination source, which includes a plurality of vertical cavity surface emitting lasers (VCSELs), the plurality of VCSELs configured to emit an electromagnetic discharge within a first frequency band, and a metalens array physically separated from the plurality of VCSELs, the metalens array including a plurality of metalenses, each of the metalenses having one or more optical structures, the metalens array positioned with respect to the VCSELs such that at least a portion of the electromagnetic discharge emitted by the plurality of VCSELs passes through at least a portion of the plurality of metalenses included in the metalens array.

In some implementations, the plurality of metalenses are distributed in a regular pattern on a first surface of a substrate of the metalens array. In some implementations, the plurality of metalenses are distributed in an irregular pattern across a first surface of a substrate of the metalens array.

In some implementations, the one or more optical structures includes a plurality of optical structures. In some implementations, a first metalens in the plurality of metalenses has a first dimension transverse to an optical path through the first metalens. In some implementations, the metalens array has a focal length of less than 700 micrometers (μm). In some implementations, at least one metalens in the plurality of metalenses has a diameter transverse to an optical axis of the at least one metalens, the diameter less than 100 micrometers (μm). In some implementations, the plurality of optical structures has two or more different physical geometries. In some implementations, the plurality of optical structures are composed of one or more of the following: TiO2, Ta2O5, amorphous Si, c-Si, GaN, and Si3N4.

In some implementations, the illumination source further includes a first substrate that includes a first material, the first substrate having a first surface and a transversely opposed second surface, and a second substrate that includes a second material, the second substrate having a first surface and a transversely opposed second surface, in which the plurality of VCSELs are formed on the first surface of the first substrate, the metalens array is formed on the first surface of the second substrate, and the first surface of the first substrate is disposed opposite the first surface of the second substrate such that a gap exists between an emission surface of each of at least some of the plurality of VCSELs and the first surface of the second substrate. In some implementations, the gap has a first distance of less than 250 nanometers measured from an emission surface of each of at least some of the plurality of VCSELs and the first surface of the second substrate.

In some implementations, the illumination source further includes a first substrate that includes a first material, the first substrate having a first surface and a transversely opposed second surface, and a second substrate that includes a second material, the second substrate having a first surface and a transversely opposed second surface, in which the plurality of VCSELs are formed on the first surface of the first substrate, the metalens array is formed on the first surface of the second substrate, and the second surface of the second substrate is disposed proximate an emission surface of each of at least some of the plurality of VCSELs such that the electromagnetic energy emitted by the at least some of the plurality of VCSELs passes through the second substrate prior to passing through at least some of the plurality of metalenses in the metalens array. In some implementations, the illumination source further includes an encapsulation layer disposed proximate at least a portion of the plurality of metalenses in the metalens array. In some implementations, the second material has a first refractive index value;

the encapsulation layer has a second refractive index value, and the second refractive index value is within ±10% of the first refractive index value. In some implementations, the encapsulation layer includes at least one of SiO2 or amorphous A1203. In some implementations, the encapsulation layer includes a chemical-mechanically polished encapsulation layer. In some implementations, the second substrate is bonded to the emission surface of the at least some of the plurality of VCSELs using one or more adhesives. In some implementations, the one or more adhesives include an ultraviolet activated adhesive. In some implementations, each of the plurality of VCSELs includes a VCSEL having a first height measured with respect to the first surface of the first substrate, and the one or more adhesives includes an adhesive layer having a thickness at least equal to the first height.

In some implementations, the illumination source further includes a flip-chip substrate that includes a first material having a first refractive index value, the flip-chip substrate having a first surface and a transversely opposed second surface, in which the plurality of VCSELs are formed on the first surface of the flip-chip substrate, the metalens array is formed on the second surface of the flip-chip substrate, the plurality of metalenses including a second material having a second refractive index value, and the electromagnetic discharged emitted by at least some of the plurality of VCSELs passes through the flip-chip substrate prior to passing through at least some of the plurality of metalenses. In some implementations, the flip-chip substrate includes at least one of fused silica, glass, sapphire glass, Si, MgF2, Si3N4, GaN, and GaAs. In some implementations, the illumination source further includes an encapsulation layer disposed proximate at least a portion of the metalens array. In some implementations, the second material includes a material having a first refractive index value, the encapsulation layer includes a material having a second refractive index value, and the second refractive index value is within ±10% of the first refractive index value.

In some implementations, the illumination source further includes a flip-chip substrate that includes a first material having a first refractive index value, the flip-chip substrate having a first surface and a transversely opposed second surface, and a buffer layer having a first surface and a second surface, at least a portion of the buffer layer first surface disposed proximate at least a portion of the flip-chip substrate second surface, the buffer layer including one or more materials having a second refractive index value, in which the plurality of VCSELs are formed using the first material on the flip-chip substrate first surface, the metalens array is formed on at least a portion of the second surface of the buffer layer, the plurality of metalenses in the metalens array including one or more materials having third refractive index value, and the electromagnetic discharge emitted by at least some of the plurality of VCSELs passes through the flip-chip substrate and the buffer layer prior to passing through at least some of the plurality of metalenses. In some implementations, the illumination source further includes an encapsulation layer disposed proximate at least a portion of the metalens array. In some implementations, the first refractive index value is greater than the second refractive index value. In some implementations, the encapsulation layer includes one or more materials having a fourth refractive index value, and the second refractive index value is greater than the fourth refractive index value. In some implementations, the third refractive index value is greater than the second refractive index value.

Further implementations disclosed herein include an illumination source manufacturing method, the method including forming an epitaxial layer on a first surface of a GaAs substrate, forming a metalens array that includes a plurality of metalenses on a second surface of the GaAs substrate, the second surface of the GaAs substrate transversely opposed across a thickness of the GaAs substrate from the first surface of the GaAs substrate, depositing a protective layer across at least a portion of the plurality of metalenses, forming a plurality of vertical cavity surface emitting lasers (VCSELs) on at least a portion of the epitaxial layer, depositing metallic interconnects proximate at least some of the plurality of VCSELs, and removing at least a portion of the protective layer from the portion of the plurality of metalenses.

In some implementations, a nanolithographic technique is used to form the metalens array on the second surface of the GaAs substrate.

### BRIEF DESCRIPTION OF THE DRAWINGS

Features and advantages of various implementations of the claimed subject matter will become apparent as the following Detailed Description proceeds, and upon reference to the Drawings, wherein like numerals designate like parts, and in which:

FIG. 1A depicts a schematic of an example semiconductor package that includes a vertical cavity surface emitting laser (VCSEL) array emitting electromagnetic energy through a metalens array that is spaced apart from the VCSEL array by a distance to provide a uniform or near uniform far-field illumination, in accordance with at least one implementation described herein.

FIG. 1B depicts the electromagnetic output of an example VCSEL and the divergence of the electromagnetic output between the discharge surface of the VCSEL and the incident surface of the metalenses forming the metalens array for a system such as depicted in FIG. 1A, in accordance with at least one implementation described herein.

FIG. 1C depicts an example optical calculation of an approximate far field shape for a metalens array such as depicted in FIG. 1A using a thin lens approximation, in accordance with at least one implementation described herein.

FIG. 2 depicts an example system in which the metalens array faces the VCSEL array 110, in accordance with at least one implementation described herein.

FIG. 3 depicts another example system in which the metalens array that includes an encapsulation layer is stacked with and physically coupled to the VCSEL array using an adhesive layer disposed between the metalens array substrate and the emission surfaces of the VCSELs, in accordance with at least one implementation described herein.

FIG. 4 depicts another example system using flip-chip technology to deposit the VCSEL array on a first side of a flip-chip substrate and the metalens array on a second side of the flip-chip substrate such that the electromagnetic emission from the VCSELs passes through the flip-chip substrate and through the metalens array, in accordance with at least one implementation described herein.

FIG. 5 depicts another example system using flip-chip technology to deposit the VCSEL array on a first side of a flip-chip substrate and the metalens array on a second side of the flip-chip substrate such that the electromagnetic emission from the VCSELs passes through the flip-chip substrate, through a low refractive index buffer layer, and through the metalens array, in accordance with at least one implementation described herein.

FIG. 6 depicts an example process for fabricating a flip-chip that includes both the VCSEL array and the metalens array, in accordance with at least one implementation described herein.

Although the following Detailed Description will proceed with reference being made to illustrative implementations, many alternatives, modifications and variations thereof will be apparent to those skilled in the art.

### DETAILED DESCRIPTION

Vertical cavity laser or VCSEL arrays are important visible and infra-red (IR) light sources in many applications, including dot display patterns for face recognition, uniform illumination for biometrics (face recognition), gesture recognition, LiDAR, and other applications. Such arrays can operate both in continuous and pulsed modes at eye-safe power levels. The individual VCSELs are characterized by relatively narrow divergence, azimuthal symmetry in the beam pattern, and high power with low speckle when used in arrays. These are all good characteristics for laser-based illumination.

One issue with any type of laser light source for illumination is creating a speckle-free far-field pattern with a desired, uniform illumination pattern. Another issue is the alignment of the illumination source optics required to generate the desired illumination pattern. A third issue, particularly with surface mount and other miniature illumination sources, is that the illumination source (i.e., the metalens and VCSEL system) should be sufficiently compact to permit packaging the system in thin profile devices such as mobile phones. An additional issue is the illumination patterns must often meet very specific radiant intensity distributions, which can be difficult to achieve with ordinary refractive micro-optics.

As used herein the term “metalens” refers to a lens formed using one or more metamaterials. A metalens includes a plurality of three-dimensional (3D) structures fabricated using one or more metamaterials. A metamaterial includes any material whose electromagnetic properties are obtained from the atomic or crystalline structure of the material rather than the chemical composition of the material. In some instances, each of the plurality of 3D structures may include a 3D pillar having a similar physical geometry (prismatic, frustoconical, conical, cylindrical, cubic, polygonal, oval, etc.). In some instances, each of the plurality of 3D structures may include at least two three-dimensional pillars, each having different physical geometries. Each of the 3D structures included in a metalens include a structure that extends a distance (i.e., a height) from the surface of the metalens array substrate on which the 3D structures are disposed or formed. Each of the 3D structures included in a metalens may extend the same or a similar height from the surface on which the 3D structures are disposed or formed. Each of the 3D structures includes an optical axis extending longitudinally through the 3D structure. The optical axis of each of the 3D structures included in a metalens may be parallel. The term “metalens array” refers to a plurality of metalenses that are typically disposed in a regular pattern, irregular pattern, or are randomly distributed on a surface.

As used herein, the term “physical geometry” refers to both the geometric shape and dimensions of the referenced object. For example, the physical geometry of a prismatic 3D structure may be a polygonal structure with side length, radius, and height dimensions. In another example, the physical geometry of a cylindrical 3D structure may include diameter/radius and height dimensions of the cylindrical structure.

The systems and methods disclosed herein beneficially address the above identified issues using an array of metalenses illuminated using an array of VCSELs, where the VCSEL positions are uncorrelated to the individual metalenses included in the metalens array or 3D structures included in the metalens The metalens array approach provides several advantages, particularly by allowing the use of low-profile VCSEL packages having a minimal thickness or height dimension. The surface of the metalens array is generally sub-micron in height and can be applied to a substrate material having a thickness less than 1 millimeter (mm), such as 200 micrometers (μm). The systems and methods disclosed herein beneficially do not require alignment of the lenslets in the array with respect to the location of the VCSELs.

The systems and methods disclosed herein beneficially provide high quality imaging and illumination with very short focal lengths or optical path lengths, often much less than 100 μm. This allows one to place the full metalens array substrate very close to or even in contact with the array of VCSELs. The systems and methods disclosed herein beneficially minimize or even eliminate artifacts associated with a standard plastic or glass micro-lens array solution which occur due to the boundaries and curvature discontinuities. Advantageously, unlike conventional diffractive optic lenses which require larger scale vertical structures that vignette light from neighboring structures and yield artifacts, the metalens arrays disclosed herein are free from such artifacts. The metalens arrays disclosed herein provide greater flexibility over refractive and conventional diffractive optics in terms of creating various desired illumination patterns as nearly arbitrary phase (and amplitude) transformations of the incoming wavefront can be implemented.

Due to the flexibility of both the possible shapes of the metalens and phase/amplitude transfer function, the metalens array approach is better suited to transforming wavefronts generated by VCSELs, which can be superpositions of various optical modes, beyond TEM00. Additionally, the systems and methods disclosed herein easily permit each metalens lenslet to have different characteristics. This can further aid the generation of desired far-field patterns, including addition of astigmatic effects in the lens design, non-uniform tiling which can further improve pattern uniformity, and further reduction of diffraction artifacts caused by lens boundaries. The systems and methods described herein beneficially provide a relatively thin and flat optical lens composed of structures formed using one or more transparent materials having a relatively high refractive index, such as TiO₂. The systems and methods disclosed herein include a plurality of individual 3D structures, such as posts, formed in concentric layers that provide a defined phase shift and minimal dispersion across all or a portion of the visible electromagnetic spectrum. Such metalens arrays may be configured to provide any desired focal length while reducing or even eliminating chromatic dispersion.

Various configurations are possible. For example, the metalens array could face the VCSEL array with the metalens substrate facing air. This simple configuration allows for straightforward hermetic sealing of the package and does not require a protective encapsulation of the metalens array which is inherently sealed within the package. A thinner package could be obtained by gluing the metalens substrate directly to the VCSEL array, with the metalens array facing air. In this case an additional encapsulation and/or passivation layer is applied to protect the metalens array. Due to the higher refractive index of the encapsulation/passivation layer and intervening waveguide modes introduced by the passivation layer, the system design may be more complex and achieving the highest efficiency may be more difficult. A third configuration is to operate the VCSEL in a flip-chip configuration, whereby laser emission occurs after passing through the VCSEL substrate, and the non-substrate side of the individual VCSELs includes a high reflector rather than output coupling mirror. In this case, the metalens substrate could be glued or bonded directly to the VCSEL substrate. Alternatively, the metalens pillars could be disposed proximate the VCSEL substrate. The 3D structures included in each metalens forming the metalens array may also be directly etched in the VCSEL substrate material.

An illumination source is provided. The illumination source may include a plurality of vertical cavity surface emitting lasers (VCSELs), the plurality of VCSELs to provide an electromagnetic discharge within a first frequency band, and a metalens array physically separated from the plurality of VCSELs, the metalens array including a plurality of metalenses, each of the metalenses having one or more optical structures arranged in a pattern, the metalens array positioned with respect to the VCSELs such that at least a portion of the electromagnetic discharge produced by the plurality of VCSELs passes through at least a portion of the plurality of metalenses included in the metalens array.

An illumination source manufacturing method is provided. The method may include: forming a series of epitaxial layers on a first surface of a GaAs substrate; forming a plurality of metalenses to form a metalens on a second surface of the GaAs substrate, the second surface of the GaAs substrate transversely opposed across a thickness of the GaAs substrate from the first surface of the GaAs substrate; depositing a protective layer across at least a portion of the plurality of metalenses; forming a plurality of vertical cavity surface emitting lasers (VCSELs) on at least a portion of the epitaxial layer; depositing metallic interconnects proximate at least some of the plurality of VCSELs; and removing at least a portion of the protective layer from the portion of the plurality of metalenses.

As used herein, the term “visible electromagnetic spectrum” includes all or a portion of the human visible electromagnetic spectrum that extends from 360 nanometers (nm) wavelength to 790 nm wavelength.

As used herein, materials referred to as “transparent” transmit all or a portion of the incident electromagnetic energy. For example, a material or structure referred to as being “transparent to at least a portion of the visible electromagnetic spectrum” refers to a material or structure that is at least partially transparent to electromagnetic energy having wavelengths in the range of 360 nm to 790 nm. Such materials may or may not pass electromagnetic energy in other portions (e.g., ultraviolet, infrared) of the electromagnetic spectrum. In another example, a material or structure referred to as being “at least partially transparent to at least a portion of the near infrared spectrum” refers to a material or structure that is at least partially transparent to electromagnetic energy having wavelengths greater than 790 nm.

As used herein, the term “on-chip” or elements, components, systems, circuitry, or devices referred to as “on-chip” include such items integrally fabricated with the processor circuitry (e.g., a central processing unit, or CPU, in which the “on-chip” components are included, integrally formed, and/or provided by CPU circuitry) or included as separate components formed as a portion of a multi-chip module (MCM) or system-on-chip (SoC).

As used herein, the term “uniform or near-uniform far-field illumination” refers to an illumination in which the luminosity measured at a single point on a flat screen varies by less than ±20% of the average luminosity measured across the entire flat screen.

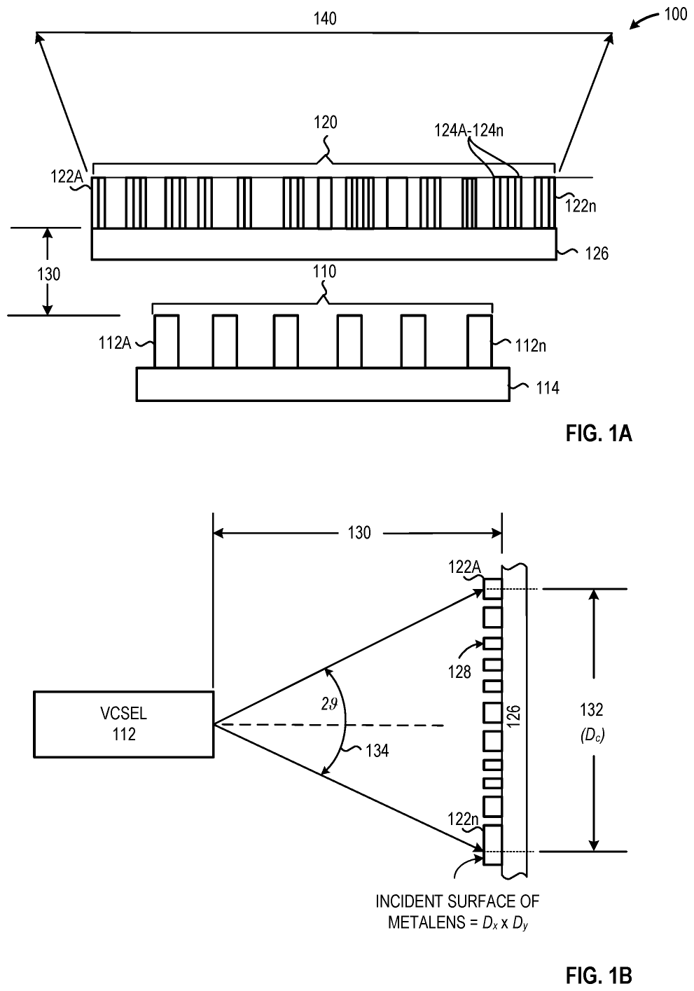

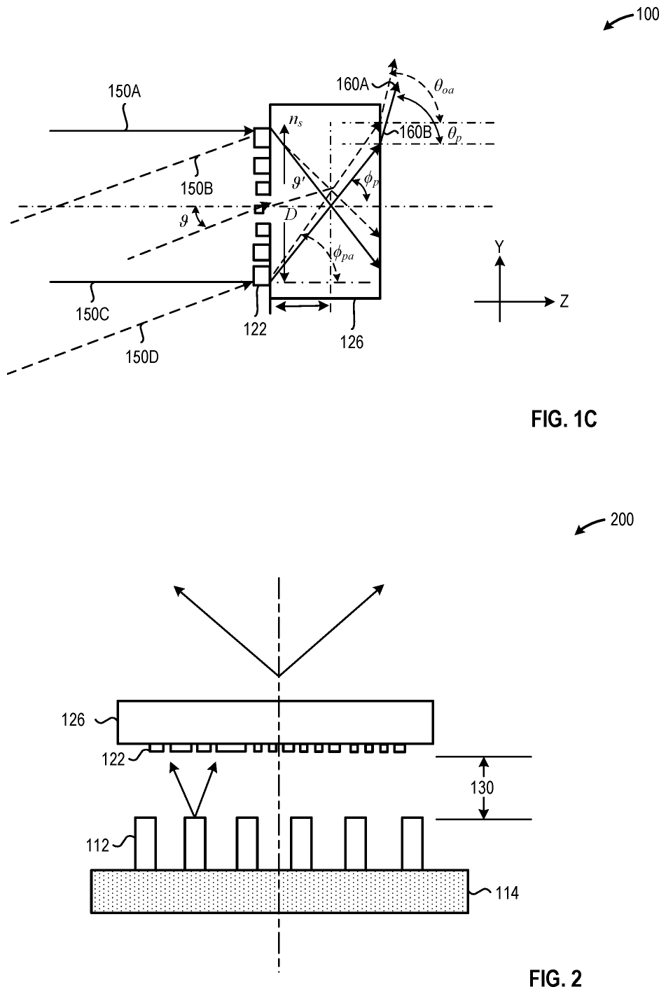

FIG. 1A depicts a schematic of an example semiconductor package 100 that includes a vertical cavity surface emitting laser (VCSEL) array 110 emitting electromagnetic energy through a metalens array 120 that is spaced apart from the VCSEL array 110 by a distance 130 to provide a uniform or near uniform far-field illumination 140, in accordance with at least one implementation described herein. FIG. 1B depicts the electromagnetic output of an example VCSEL 112 and the divergence of the electromagnetic output between the discharge surface 116 of the VCSEL and the incident surface 128 of the metalenses 122 forming the metalens array 120 for a system such as depicted in FIG. 1A, in accordance with at least one implementation described herein. FIG. 1C depicts an example optical calculation of an approximate far field shape for a metalens array 120 such as depicted in FIG. 1A using a thin lens approximation, in accordance with at least one implementation described herein.

As depicted in FIG. 1A, the VCSEL array 110 may include a plurality of VCSELs 112A-112n (collectively, “VCSELs 112”) and the metalens array 120 may include a plurality of metalenses 122A-122n (collectively, “metalenses 122”), each of the metalenses 122 including the same or a different number of 3D structures 124A-124n (collectively, “3D structures 124,” or singly, “3D structure 124”). As depicted in FIG. 1, in at least some implementations, the VCSELs 112 may be disposed on, about, or across a substrate 114. In some implementations, the metalenses 122 may be disposed in, on, about, or across at least a portion of a metalens array substrate 126.

In operation, each of the VCSELs 112 emits electromagnetic energy in at least a portion of the electromagnetic spectrum. For example, the VCSELs 112 may emit electromagnetic energy in all or a portion of the visible spectrum (390 nanometers (nm)<λ<760 nm), all or a portion of the infrared spectrum (λ, >760 nm), or any combination thereof. The electromagnetic energy passes through the metalens array substrate 124 and passes through one or more metalenses 122. The metalens array 120 creates a uniform far-field illumination on a flat screen 140.

The VCSELs 112 generate an electromagnetic output that falls incident upon the metalens array 120 disposed a distance 130 from the discharge point of the VCSELs 112. In implementations, the location (e.g., the centerline) of each of the VCSELs 112A-112n may be randomly located with respect to the location (e.g., the optical axis) of the metalenses 122 forming the metalens array 120. In implementations, the location (e.g., the centerline) of each of the VCSELs 112A-112n may be uncorrelated to the location (e.g., the optical axis) of the metalenses 122 forming the metalens array 120. Randomizing or decorrelating the location of each of the VCSELs with respect to the metalenses minimizes or even eliminates the mutual reinforcement of diffraction artifacts due to the size of each metalens and minimizes the occurrence of Moire effect artifacts in the far-field illumination of the flat screen 140.

FIG. 1B depicts a typical distance 130 between the discharge surface of the VCSEL array 110 and the incident surface of the metalens array 120, given the full-width far-field divergence angle from a VCSEL. At a typical distance 130, the field from a single VCSEL 112 covers several metalenses 122.

FIG. 1C depicts the geometry useful for calculating the expected far-field divergence based on edge-ray propagation. The ray geometry is shown in FIG. 1C for the far-field projection along the y-axis. A similar geometry would apply for far-field projection along the x-axis. A single metalens 122 is assumed to have a rectangular shape with dimensions Dₓ and D_{y}. In this example, the metalens 122 is assumed to be convex (generates a converging spherical wavefront for collimated incident light) and has focal plane in the substrate material of distance f. In FIG. 1C, the bold rays 150A-150D (collectively, “rays 150”) depict rays that lead to boundary edges in the far-field. These include incident parallel rays from the VCSELs 112 and from the highest angle VCSEL rays. Note that the location of a VCSEL 112 with respect to each metalens 122A-122n in the metalens array 120 is effectively random or uncorrelated. Thus, a given metalens 112 may be illuminated by both parallel and highest off-axis rays from nearby VCSELs 112 which can have random locations with respect to the optical axis of a given metalens 122. In general, the location of the parallel and highest angle rays 150 may appear at random locations on the incident surface 128 of any metalens 122 forming the metalens array 120. Referring again to FIG. 1C, the bold rays 150 do lead to the highest angle far-field rays 160A and 160B (collectively “far-field rays 160”). It is preferable to fully illuminate the metalens array surface and not have unilluminated regions. Typically, the number of VCSELs 112 are less than the number of metalenses 122 included in the metalens array 120. These considerations imply D_{c}>Dₓ and D_{c}>D_{y}, where the incident surface of each metalens 122 is a generally rectangular area Dₓ x D_{y} and the diameter of the area illuminated by a single VCSEL is D_{c}, so that any given VCSEL 112 will illuminate a given metalens 122 with some subset of all the rays falling on the incident surface 128 of the metalens 122. Generally, the incident off-axis rays 150 will contribute to the higher angle far field rays 160, but these will have lower radiant intensities, contributing less to the far-field illumination.

As an example, a metalens 122 may impart a hyperboloidal phase response so parallel collimated light reaches a diffraction limited focus, regardless of lens size. The desired phase delay Ψ imparted by the metalens 122 as a function of radius (r) and focal length (f) is given by:

$$Ψ = {mod}_{2 π} [ {Ψ}_{0} + \frac{2 π {n}_{s}}{{λ}_{0}} ( f - \sqrt{{f}^{2} + {r}^{2}} ) ] \qquad ( 1 )$$

where λ₀=free space wavelength if incident energy.

In Eq. Error! Reference source not found., the argument of the modulo 2π a phase function decreases with increasing radius. This compensates for the increasing phase delay required to generate a converging spherical wave propagating in the substrate and emanating from the metalens array 120. The constant phase factor ψ₀ corresponds to the finite phase delay at the optic axis of the lens that exists. In general, the starting pillar diameters chosen for the center of the metalens will determine this initial phase delay. In this implementation ψ₀=π represents one possibility used in the current implementation, but ψ₀ can be an arbitrary value often set to zero, i.e, ψ₀=0. Note that the phase response depends on the refractive index of the metalens array substrate 126 (nₛ) for configuration of this implementation. Eq. Error! Reference source not found. can be generalized slightly to image a point source from a finite distance L rather than from infinity. It is also possible to take the real VCSEL field into account at a finite distance L, yielding a more complicated phase transformation. In various implementations, a variety of possible phase functions may be used and may include additional polynomial terms added to Eq. Error! Reference source not found., to achieve a desired far-field radiant intensity. However, in such implementations, the phase function should include at least a term of the form of Eq. Error! Reference source not found., its polynomial approximation, or related point-source imaging terms, so that the overall phase function focuses at a real or virtual focus. Various algorithms can be used to find a phase function given a desired far-field radiant intensity distribution.

One design criteria for the metalens array 120 may be based on a periodic lattice that should behave as a sub-wavelength grating; that is, any local portion of the metalens array 120 should not generate diffraction orders above zero-order. For the case of a hexagonal lattice with period P, one can show that a given order (m, n) will yield a non-propagating mode in a medium of refractive index nₘ if the following condition is met:

$$P < \frac{2 {λ}_{0}}{\sqrt{3} {n}_{m}} \sqrt{{m}^{2} + {n}^{2} - mn} . \qquad ( 1 )$$

For the case of metalenses 122 disposed on a fused silica metalens array substrate 126 with nₛ=1.451 and λ₀=940 nm, P<704 nm. And into air, P<1085 nm. For high lens efficiency, P must satisfy Eq. (1) for air (or for an encapsulation layer 302 disposed about the metalens array 120). It is also desirable to satisfy Eq. (1) for the metalens array substrate 126 as well to keep higher order modes from backscattering and leading to loss.

The local phase and power transmission through the metalens array may be determined by running periodic simulations, such as rigorous coupled-wave analysis (RCWA), on the hexagonal lattice for metalenses 122A-122n of a given refractive index nₚ, height h, and diameter d. Generally, the height of the metalens is fixed so that binary lithography may be used, and the diameter is varied to map out the phase and power transmission. A search can be performed over heights h and periods P which simultaneously yield an acceptably high transmission such as >80%, >85%, >90%, or >95% with a phase response spanning very close to or greater than 2π. This then yields a set of metalens diameters that can locally to match the target phase in Eq. Error! Reference source not found..

Referring back to FIG. 1A, in at least some implementations, the VCSELs 112 may be disposed in, on, about, or across all or a portion of a surface of the VCSEL substrate 114. In implementations, one or more conductors, traces, vias, or similar electrically conductive structures may operably couple each of the VCSELs 112 to a pad, pin, or similar electrically conductive connector on a surface of the VCSEL substrate 114 transversely opposed across a thickness of the VCSEL substrate 114 to the surface upon which the VCSELs 112 are disposed.

The 3D structures 124 included in each of the metalenses 122 may be fabricated using one or more high refractive index inorganic materials for robustness and field confinement. As used herein, the term “high refractive index” refers to materials, compositions, and/or combinations of materials having a refractive index of greater than 2.0. Example high refractive index materials include but are not limited to, TiO₂, Ta₂O₅, amorphous Si, c-Si, GaN, GaP-InP, GaInAs, Si₃N₄, and other similar lossless or nearly lossless optical materials that can be deposited as a thin film. The 3D structures 124 may be formed, deposited, or otherwise disposed in, on, or about all or a portion of a substrate using lithographic techniques, including but not limited to UV and deep-UV photolithography, e-beam lithography, and nano-imprint techniques. The electromagnetic energy emitted by the VCSELs 112 enters the incident surface 128 of the 3D structure 124. In some implementations, the incident surface 128 may be disposed proximate the metalens substrate 122. In other implementations, the incident surface 128 may be disposed remote from the metalens substrate 122.

The 3D structures 124 forming each of the metalenses 122A-122n included in the metalens array 120 may have any physical geometry (i.e., cross-sectional profile) and any physical dimensions. Each metalens 122 may include one or more 3D structures 124. Example non-limiting 3D structure physical geometries include polygonal pillars (triangular, square, rectangular, pentagonal, hexagonal, etc.), oval pillars, and cylindrical pillars. In some implementations, each of some or all of the metalenses 122A-122n may include the same number of 3D structures 124. In some implementations, each of some or all of the metalenses 122A-122n may include different numbers of 3D structures 124. In some implementations, each of some or all of the metalenses 122A-122n may include 3D structures 124 having the same physical geometry. In some implementations, each of some or all of the metalenses 122A-122n may include 3D structures 124 having two or more different physical geometries. In some implementations, each of some or all of the metalenses 122A-122n may include 3D structures 124 having the same dimensions (diameter, perimeter, radii, circumference, etc.). In some implementations, each of some or all of the metalenses 122A-122n may include 3D structures 124 having two or more different dimensions. In some implementations, each of some or all of the metalenses 122A-122n may include 3D structures 124 having the same height (i.e., height measured from the 3D structure surface distal from the surface of the metalens array substrate to the surface of the metalens array substrate). In some implementations, each of some or all of the metalenses 122A-122n may include 3D structures 124 having two or more different heights. For example, in at least some implementations, each of the metalenses 122 forming the metalens array 120 may include one or more 3D structures 124, such as one or more cylindrical pillars or nano-elements having a single fixed height, which may be less than 1 μm for applications where the VCSELs 112 produce an electromagnetic output in the visible and/or near infrared electromagnetic spectrum.

In implementations, the plurality of metalenses 122A-122n forming the metalens array 120 may be disposed in a fixed lattice formation or pattern on the metalens array substrate 126. Example fixed lattice formations include but are not limited to a square lattice formation, a hexagonal lattice formation, a triangular lattice formation, a spiral lattice formation, or a concentric lattice formation. In other implementations, the plurality of metalenses 122A-122n forming the metalens array 120 may be disposed in a random lattice formation or pattern on the metalens array substrate 126. In implementations, the plurality of metalenses 122A-122n may have two or more different physical dimensions to alter the local phase and amplitude of the incident wavefront at sub-wavelength lateral length scales. In some implementations, the one or more 3D structures 124 included in a metalens 122 may be fabricated using the same material (homo-material) as the metalens array substrate 126. In some implementations, such homo-material 3D structures may be etched directly into the metalens array substrate 126. In other implementations the 3D structures 124 included in a metalens 122 may be fabricated using one or more materials that differ (hetero-material) from the metalens array substrate 126. In such implementations, the 3D structures 124 included in each of the metalenses 122A-122n may be formed by deposition of a layer of the 3D structure material, followed by a material removal process such as etching or laser ablation.

In implementations, each of the plurality of metalenses 122A-122n forming the metalens array 120 may have the same or different focal lengths. In implementations, metalenses 122A-122n may have a focal length of less than about 500 micrometers (μm), 400 μm, 300 μm, 200 μm, or 100 μm. In implementations, each metalens 122 included in the plurality of metalenses 122A-122n forming the metalens array 120 may have the same outside dimension. In other implementations, each metalens 122 included in the plurality of metalenses 122A-122n forming the metalens array 120 may have two or more different outside dimensions. Each metalens 122A-122n included in the metalens array 120 may have an outside dimension (i.e., diameter) of about 300 μm or less, 200 μm or less, 100 μm or less, 75 μm or less, or 50 μm or less and would take on the shape approximating that of the projected illumination area. For example, if the aspect ratio of a desired rectangular far-field illumination is 4:3, then each of the metalenses 122A-122n would be rectangular and have approximately the same 4:3 aspect ratio.

In implementations, the metalens array substrate 126 may include a hetero-material substrate that includes a variety of crystalline or amorphous transparent materials in the desired wavelength region. Example hetero-material metalens array substrates 126 include but are not limited to fused silica, glass, sapphire, Si, MgF₂, Si₃N₄, GaN, GaAs, certain polymers, and similar materials. In such implementations, such hetero-material metalens array substrates 126 should be compatible with the material removal or etching processes used to create the 3D structures 124 forming the metalenses 122A-122n in the hetero-material metalens array substrate.

FIG. 2 depicts an example system 200 in which the metalens array 120 faces the VCSEL array 110, in accordance with at least one implementation described herein. As depicted in FIG. 2, the incident surface of the metalens array substrate 126 facing the VCSEL array 110 is disposed a distance 130 from the emission surface of each of the VCSELs 112.

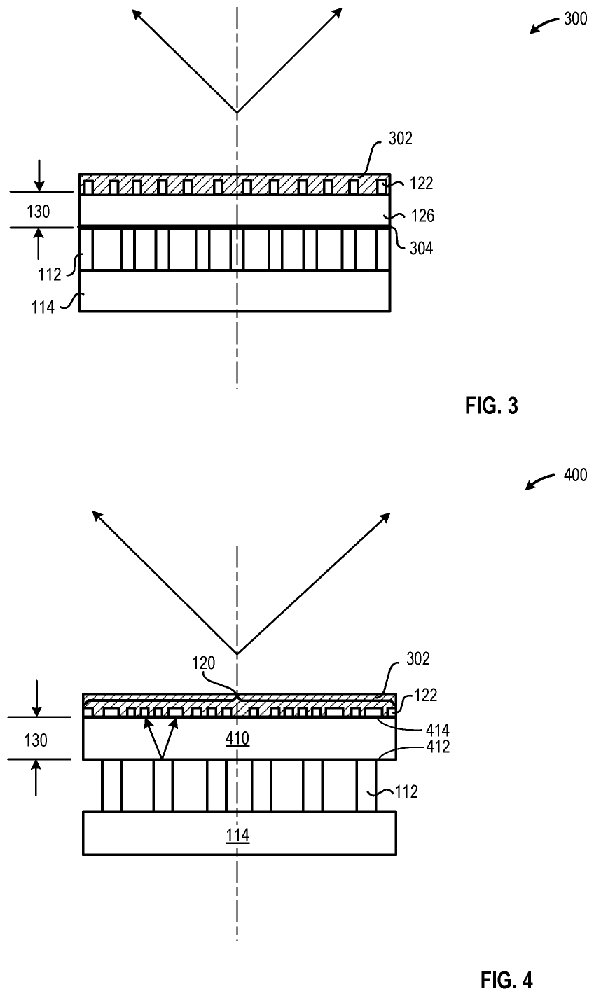

FIG. 3 depicts another example system 300 in which the metalens array 120 that includes an encapsulation layer 302 is stacked with and physically coupled to the VCSEL array 110 using an adhesive layer 304 disposed between the metalens array substrate 126 and the emission surfaces of the VCSELs 112, in accordance with at least one implementation described herein. In implementations, the adhesive layer 304 may include any type of thermally curable, chemically activated, or photochemically activated adhesive. In at least some implementations, the adhesive layer 304 may include a UV-curable adhesive. In such implementations, the adhesive may have a refractive index similar to (i.e., within a range of ±20%) the refractive index of the metalens array substrate 126.

In implementations, the encapsulation layer 302 may be conformal, filling at least a portion of the spaces between the metalenses 122A-122n. In at least some implementations, the encapsulation layer 302 may completely fill the spaces between the metalenses 122A-122n. In other implementations, the encapsulation layer 302 may extend above the discharge surfaces of the metalenses 122A-122n. The encapsulation layer 302 may include one or more materials, one or more compounds, or one or more combinations of materials. In some implementations, the encapsulation layer material may have a relatively low refractive index (e.g., a refractive index of less than 2.0) to maintain field confinement in the metalenses 122A-122n. Example materials suitable for use as an encapsulation layer 302 include but are not limited to SiO₂ and amorphous Al₂O₃. The encapsulation layer 302 may be deposited, applied, or otherwise distributed in, on, about, or around the metalenses 122A-122n using one or more material deposition techniques, such as atomic layer deposition (ALD). In some implementations, the exposed surface of the encapsulation layer 302 may be optically flat. In implementations, the exposed surface of the encapsulation layer 302 may be finished using one or more finishing techniques such as chemical-mechanical polishing (CMP).

In some implementations, the adhesive layer 304 may extend between the VCSELs 112 and may extend to the surface of the VCSEL substrate 114. In such implementations, the metalens array substrate 126 may be bonded to the VCSEL array 110 in a vacuum environment and the thickness of the adhesive layer 304 will be greater than the height of the VCSELs 112 such that the adhesive layer 304 covers the emission surfaces of the VCSELs 112 included in the VCSEL array 110. In such implementations, modification of the VCSEL output coupling Bragg mirrors may be required due to the VCSEL electromagnetic emission going directly into a higher refractive index material (i.e., the adhesive layer 304) than air. The metalenses 122 now focus in air.

FIG. 4 depicts another example system 400 using flip-chip technology to deposit the VCSEL array 110 on a first side 412 of a flip-chip substrate 410 and the metalens array 120 on a second side 414 of the flip-chip substrate 410 such that the electromagnetic emission from the VCSELs 112 passes through the flip-chip substrate 410 and through the metalens array 120, in accordance with at least one implementation described herein. As depicted in FIG. 4, the VCSEL array 110 may be operably coupled to a VCSEL substrate 114 such that the electromagnetic energy is emitted from the VCSELs 112A-112n into and through the flip-chip substrate 410. As depicted in FIG. 4, the metalenses 122A-122n include one or more relatively high refractive index materials, compounds, or combinations of materials (i.e., refractive index greater than 2.0) and may be formed, deposited, or disposed on the second surface 414 of the flip-chip substrate 410. The encapsulation layer 302 is applied to the second surface 414 of the flip-chip substrate 410 and conformally coats and covers the metalenses 122A-122n without gaps. The encapsulation layer 302 provides an optically flat surface through which the electromagnetic energy (e.g., visible or NIR electromagnetic energy) exiting the metalens array 120 passes.

In at least some implementations, the flip-chip configuration may be fabricated by first forming the VCSEL array 110 on the first surface 412 of the flip-chip substrate 410 followed by forming the metalens array 120 on the second surface 414 of the flip-chip substrate 410. In such implementations, the VCSELs 112A-112n may be temporarily encapsulated in a protective layer that can be easily and safely removed upon completion of the metalens array 120 fabrication. In such implementations, another process may be mounting the VCSEL flip-chip in a sealed carrier which will protect the VCSELs 112A-112n from the process steps used to fabricate the metalens array 120. In one example, a sealed carrier may contain the flip-chip and amorphous silicon (a-Si) may be used to form the metalenses 122 thereby maintaining the system under 200° C. during processing to prevent damage to the VCSELs 112. In other implementations, materials such as Si₃N₄ may also be useful for fabricating metalenses 122A-122n since Si₃N₄ may be deposited at temperatures in the range of 200° C. using plasma-enhanced chemical vapor deposition (PECVD). One or more lithographic and etching processes may be applied to such a-Si or Si₃N₄ films to create the metalens array 120. Similar materials suitable for low temperature deposition may be substituted to fabricate the metalenses 122A-122n. An encapsulation layer 302, such as SiO₂, may be applied to the metalens array 120 using one or more low-temperature material deposition techniques. In other implementations, the metalens array 120 may be fabricated, deposited, or otherwise formed on the second surface 414 of the flip-chip substrate 410 prior to the fabrication of the VCSEL array 110 on the first surface 412 of the flip-chip substrate 410 since deposition of a high-quality amorphous silicon may require temperatures in excess of 200° C., potentially causing damage to previously fabricated VCSELs 112A-112n.

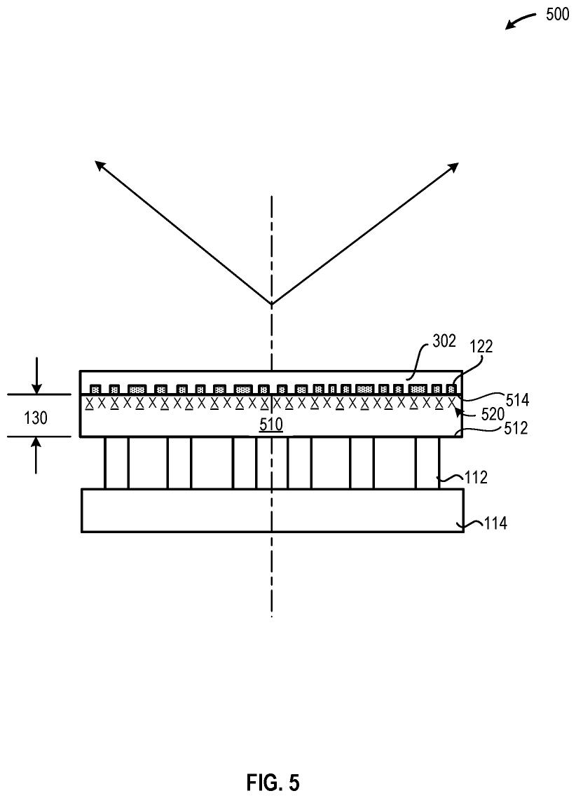

FIG. 5 depicts another example system 500 using flip-chip technology to deposit the VCSEL array 110 on a first surface 512 of a flip-chip substrate 510 and the metalens array 120 on a second surface 514 of the flip-chip substrate 510 such that the electromagnetic emission from the VCSELs 112 passes through the flip-chip substrate 510, through a low refractive index buffer layer 520, and through the metalens array 120, in accordance with at least one implementation described herein. As depicted in FIG. 5, in implementations a low refractive index buffer layer 520 may be deposited on at least a portion of the second surface 514 of the flip-chip substrate 510. In implementations, the low refractive index buffer layer 520 may have a refractive index less than the refractive index of the flip-chip substrate 510. In at least some implementations, the flip-chip substrate 510 may have a refractive index of about 2.0 or greater, 2.5 or greater, 3.0 or greater, or 3.5 or greater. In at least some implementations, the low refractive index buffer layer 520 may have a refractive index of about less than 2.0, less than 2.5, less than 3.0, or less than 3.5. In implementations, the refractive index of the buffer layer 520 may be greater than the refractive index of the encapsulation layer 302 and less than the refractive index of the flip-chip substrate 510. In implementations, the refractive index of the metalenses 122 may be greater than the refractive index of the buffer layer 520.

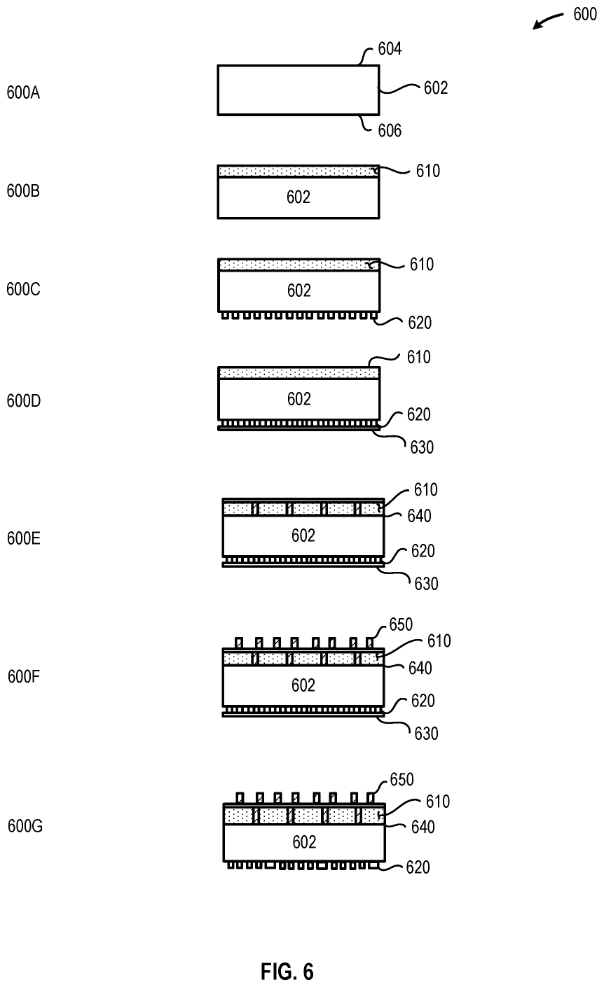

FIG. 6 depicts an example process 600 for fabricating a flip-chip that includes both the VCSEL array 110 and the metalens array 120, in accordance with at least one implementation described herein.

The fabrication commences at 600A with a flip-chip substrate 602 having a first surface 604 and a second surface 606. In implementations, the flip-chip substrate 602 may include a gallium-arsenide (GaAs) substrate.

At 600B an epitaxial layer 610 is grown on the first surface 604 of the flip-chip substrate 602.

At 600C the metalens array 620 is deposited, formed, or fabricated in, on, or about at least a portion of the second surface 606 of the flip-chip substrate 602. In implementations, the metalens array 620 may be fabricated using any material deposition and etching techniques. For example, the metalens array 620 may initially be deposited using chemical vapor deposition (CVD) or physical vapor deposition (PVD) and etched using a material removal technique such as lithography. In other implementations, the metalens array 120 may be fabricated into the second surface 606 of the flip-chip substrate 602 using one or more material removal processes, for example laser ablation. In implementations, dependent on the deposition method used for the metalens array 620, a temporary protective coating (not shown in FIG. 6) may be applied the epitaxial layer 610 to prevent deposition of the metalens material and to isolate the epitaxial layer from damage caused by the metalens etching processes. The metalens array 620 may be fabricated using nanolithography methods and compatible etching methods. In implementations, an encapsulation layer may (not shown in FIG. 6) may be applied to the metalens array 620.

At 600D a sacrificial protective layer 630 may be applied to the completed metalens array 620 to prevent damage during the remainder of the fabrication process.

At 600E the VCSEL array 640 may be deposited, formed, fabricated, or otherwise disposed in, on, about, or across at least a portion of the epitaxial layer 610 on the first surface 604 of the flip-chip substrate 602.

At 600F conductive elements 650, such as copper pillars are deposited, formed, fabricated, or otherwise disposed in, on, about, or across at least a portion of the VCSEL array 640.

At 600G, the protective layer 630 on the metalens array 620 is removed.

While FIG. 6 illustrates various operations according to one or more implementations, it is to be understood that not all of the operations depicted in FIG. 6 are necessary for other implementations. Indeed, it is fully contemplated herein that in other implementations of the present disclosure, the operations depicted in FIG. 6, and/or other operations described herein, may be combined in a manner not specifically shown in any of the drawings, but still fully consistent with the present disclosure. Thus, claims directed to features and/or operations that are not exactly shown in one drawing are deemed within the scope and content of the present disclosure.

As used in this application and in the claims, a list of items joined by the term “and/or” can mean any combination of the listed items. For example, the phrase “A, B and/or C” can mean A; B; C; A and B; A and C; B and C; or A, B and C. As used in this application and in the claims, a list of items joined by the term “at least one of” can mean any combination of the listed terms. For example, the phrases “at least one of A, B or C” can mean A; B; C; A and B; A and C; B and C; or A, B and C.

As used in any implementation herein, the terms “system” or “module” may refer to, for example, software, firmware and/or circuitry configured to perform any of the aforementioned operations. Software may be embodied as a software package, code, instructions, instruction sets and/or data recorded on non-transitory computer readable storage mediums. Firmware may be embodied as code, instructions or instruction sets and/or data that are hard-coded (e.g., nonvolatile) in memory devices.

As used in any implementation herein, the terms “circuit” and “circuitry” may comprise, for example, singly or in any combination, hardwired circuitry, programmable circuitry such as computer processors comprising one or more individual instruction processing cores, state machine circuitry, and/or firmware that stores instructions executed by programmable circuitry or future computing paradigms including, for example, massive parallelism, analog or quantum computing, hardware implementations of accelerators such as neural net processors and non-silicon implementations of the above. The circuitry may, collectively or individually, be embodied as circuitry that forms part of a larger system, for example, an integrated circuit (IC), system on-chip (SoC), desktop computers, laptop computers, tablet computers, servers, smartphones, etc.

Thus, the present disclosure is directed to systems and methods useful for providing a metasurface lens formed by a plurality of multi-component optical structures disposed on, about, or across at least a portion of the surface of a substrate member. Each of the plurality of multi-component optical structures includes a solid cylindrical core structure surrounded by a hollow cylindrical core structure such that a gap having a defined width forms between the solid cylindrical core structure and the hollow cylindrical structure surrounding the solid core. The width of the gap determines the optical performance of the metasurface lens. The multi-component optical structures forming the metasurface lens advantageously produce little or no phase shift in the electromagnetic energy passing through the metasurface lens, thereby beneficially providing an optical device having minimal or no dispersion and/or chromatic aberration.

The following examples pertain to further implementations. The following examples of the present disclosure may comprise subject material such as at least one device, a method, at least one machine-readable medium for storing instructions that when executed cause a machine to perform acts based on the method, means for performing acts based on the method and/or a system for providing a low profile metalens array that provides a relatively uniform far-field illumination using a plurality of vertical cavity surface emitting lasers (VCSELs) disposed a distance from a plurality of metalenses forming a metalens array where the VCSELs are decorrelated from the metalenses forming the metalens array.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents. Various features, aspects, and implementations have been described herein. The features, aspects, and implementations are susceptible to combination with one another as well as to variation and modification, as will be understood by those having skill in the art. The present disclosure should, therefore, be considered to encompass such combinations, variations, and modifications.

As described herein, various implementations may be implemented using hardware elements, software elements, or any combination thereof. Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth.

Reference throughout this specification to “one implementation” or “an implementation” means that a particular feature, structure, or characteristic described in connection with the implementation is included in at least one implementation. Thus, appearances of the phrases “in one implementation” or “in an implementation” in various places throughout this specification are not necessarily all referring to the same implementation. Furthermore, the particular features, structures, or characteristics may be combined in any suitable manner in one or more implementations.

What is claimed:

1. An illumination source comprising:
a plurality of vertical cavity surface emitting lasers (VCSELs), the plurality of VCSELs configured to emit an electromagnetic discharge within a first frequency band; and
a metalens array physically separated from the plurality of VCSELs, the metalens array including a plurality of metalenses, each of the metalenses having one or more optical structures, the metalens array positioned with respect to the VCSELs such that at least a portion of the electromagnetic discharge emitted by the plurality of VCSELs passes through at least a portion of the plurality of metalenses included in the metalens array.

2. The illumination source of claim 1, wherein the plurality of metalenses are distributed in a regular pattern on a first surface of a substrate of the metalens array.

3. The illumination source of claim 1, wherein the plurality of metalenses are distributed in an irregular pattern across a first surface of a substrate of the metalens array.

4. The illumination source of claim 1, wherein the one or more optical structures comprises a plurality of optical structures.

5. The illumination source of claim 4, wherein a first metalens in the plurality of metalenses has a first dimension transverse to an optical path through the first metalens.

6. The illumination source of claim 4, wherein the metalens array has a focal length of less than 700 micrometers (μm).

7. The illumination source of claim 4, wherein at least one metalens in the plurality of metalenses has a diameter transverse to an optical axis of the at least one metalens, the diameter less than 100 micrometers (μm).

8. The illumination source of claim 4, wherein the plurality of optical structures has two or more different physical geometries.

9. The illumination source of claim 4, wherein the plurality of optical structures are composed of one or more of the following: TiO₂, Ta₂O₅, amorphous Si, c-Si, GaN, and Si₃N₄.

10. The illumination source of claim 4, further comprising:
a first substrate that includes a first material, the first substrate having a first surface and a transversely opposed second surface; and
a second substrate that includes a second material, the second substrate having a first surface and a transversely opposed second surface, wherein:
the plurality of VCSELs are formed on the first surface of the first substrate;
the metalens array is formed on the first surface of the second substrate; and
the first surface of the first substrate is disposed opposite the first surface of the second substrate such that a gap exists between an emission surface of each of at least some of the plurality of VCSELs and the first surface of the second substrate.

11. The illumination source of claim 10, wherein the gap has a first distance of less than 250 nanometers measured from an emission surface of each of at least some of the plurality of VCSELs and the first surface of the second substrate.

12. The illumination source of claim 4, further comprising:
a first substrate that includes a first material, the first substrate having a first surface and a transversely opposed second surface; and
a second substrate that includes a second material, the second substrate having a first surface and a transversely opposed second surface, wherein:
the plurality of VCSELs are formed on the first surface of the first substrate;
the metalens array is formed on the first surface of the second substrate; and
the second surface of the second substrate is disposed proximate an emission surface of each of at least some of the plurality of VCSELs such that the electromagnetic energy emitted by the at least some of the plurality of VCSELs passes through the second substrate prior to passing through at least some of the plurality of metalenses in the metalens array.

13. The illumination source of claim 12, further comprising:
an encapsulation layer disposed proximate at least a portion of the plurality of metalenses in the metalens array.

14. The illumination source of claim 13 wherein:
the second material has a first refractive index value;
the encapsulation layer has a second refractive index value; and
the second refractive index value is within ±10% of the first refractive index value.

15. The illumination source of claim 14, wherein the encapsulation layer includes at least one of SiO₂ or amorphous Al₂O₃.

16. The illumination source of claim 14, wherein the encapsulation layer comprises a chemical-mechanically polished encapsulation layer.

17. The illumination source of claim 12, wherein the second substrate is bonded to the emission surface of the at least some of the plurality of VCSELs using one or more adhesives.

18. The illumination source of claim 17, wherein the one or more adhesives comprise an ultraviolet activated adhesive.

19. The illumination source of claim 17, wherein:
each of the plurality of VCSELs includes a VCSEL having a first height measured with respect to the first surface of the first substrate; and
the one or more adhesives includes an adhesive layer having a thickness at least equal to the first height.

20. The illumination source of claim 4, further comprising a flip-chip substrate that includes a first material having a first refractive index value, the flip-chip substrate having a first surface and a transversely opposed second surface, wherein:
the plurality of VCSELs are formed on the first surface of the flip-chip substrate;
the metalens array is formed on the second surface of the flip-chip substrate, the plurality of metalenses including a second material having a second refractive index value; and
the electromagnetic discharged emitted by at least some of the plurality of VCSELs passes through the flip-chip substrate prior to passing through at least some of the plurality of metalenses.

21. The illumination source of claim 20, wherein the flip-chip substrate includes at least one of fused silica, glass, sapphire glass, Si, MgF₂, Si₃N₄, GaN, and GaAs.

22. The illumination source of claim 20, further comprising an encapsulation layer disposed proximate at least a portion of the metalens array.

23. The illumination source of claim 22, wherein:
the second material comprises a material having a first refractive index value;
the encapsulation layer comprises a material having a second refractive index value; and
the second refractive index value is within ±10% of the first refractive index value.

24. The illumination source of claim 4, further comprising:
a flip-chip substrate that includes a first material having a first refractive index value, the flip-chip substrate having a first surface and a transversely opposed second surface; and
a buffer layer having a first surface and a second surface, at least a portion of the buffer layer first surface disposed proximate at least a portion of the flip-chip substrate second surface, the buffer layer including one or more materials having a second refractive index value, wherein:
the plurality of VCSELs are formed using the first material on the flip-chip substrate first surface;
the metalens array is formed on at least a portion of the second surface of the buffer layer, the plurality of metalenses in the metalens array including one or more materials having third refractive index value; and
the electromagnetic discharge emitted by at least some of the plurality of VCSELs passes through the flip-chip substrate and the buffer layer prior to passing through at least some of the plurality of metalenses.

25. The illumination source of claim 24, further comprising an encapsulation layer disposed proximate at least a portion of the metalens array.

26. The illumination source of claim 25, wherein the first refractive index value is greater than the second refractive index value.

27. The illumination source of claim 26, wherein:
the encapsulation layer includes one or more materials having a fourth refractive index value; and
the second refractive index value is greater than the fourth refractive index value.

28. The illumination source of claim 24, wherein the third refractive index value is greater than the second refractive index value.

29. An illumination source manufacturing method, the method comprising:
forming an epitaxial layer on a first surface of a GaAs substrate;
forming a metalens array that includes a plurality of metalenses on a second surface of the GaAs substrate, the second surface of the GaAs substrate transversely opposed across a thickness of the GaAs substrate from the first surface of the GaAs substrate;
depositing a protective layer across at least a portion of the plurality of metalenses;
forming a plurality of vertical cavity surface emitting lasers (VCSELs) on at least a portion of the epitaxial layer;
depositing metallic interconnects proximate at least some of the plurality of VCSELs; and
removing at least a portion of the protective layer from the portion of the plurality of metalenses.

30. The method of claim 29, wherein a nanolithographic technique is used to form the metalens array on the second surface of the GaAs substrate.
